(19) United States
(12) Patent Application Publication
(10) Pub. No.: US 2026/0338876 A1
(43) Pub. Date: Oct. 29, 2026

(54) DISCONNECTION DETECTION DEVICE AND BATTERY MONITORING DEVICE

(71) Applicant: HITACHI ASTEMO, LTD., Hitachinaka-shi, Ibaraki (JP)

(72) Inventors: Tomonori OKAMI, Hitachinaka-shi, Ibaraki (JP); Shingo TSUCHIYA, Hitachinaka-shi, Ibaraki (JP)

(21) Appl. No.: 18/881,023

(22) PCT Filed: Jul. 7, 2022
(86) PCT No.: PCT/JP2022/027007

§ 371 Date: Jan. 3, 2025

(51) Int. Cl. G01R 31/54; G01R 19/10; H02J 7/00; H02J 7/56; H02J 7/96

(52) U.S. Cl. CPC G01R 31/54; G01R 19/10; H02J 7/56; H02J 7/855; H02J 7/96

(57) ABSTRACT

A disconnection detection device includes, in a battery including battery cells connected in series, each of which connected in parallel to a discharge circuit that includes an electronic switch, a voltage detection circuit detecting a cell voltage of the battery cell, a CR low-pass filter provided in each of wirings connecting the battery cell to the voltage detection circuit, and a control unit performing equalization discharge of the discharge circuit and detecting the disconnection of the wiring based on the cell voltage, in which the electronic switch has a protection function for prohibiting transition to an ON state, and the control unit performs electricity removal of electric charges accumulated in the CR low-pass filter by operating any one of a pair of the electronic switches related to a pair of the adjacent battery cells, and detects the disconnection of the wiring based on the cell voltage after the electricity removal.

### CROSS REFERENCE TO RELATED APPLICATIONS

This is the U.S. national stage of application No. PCT/JP2022/027007, filed on Jul. 7, 2022. Priority of which is claimed and the disclosure of which is incorporated herein by reference.

### TECHNICAL FIELD

The present invention relates to a disconnection detection device and a battery monitoring device.

### BACKGROUND ART

Patent Document 1 discloses a cell balance control device. The cell balance control device includes a discharge circuit that is constituted with a series circuit of a bypass resistor and a switching element and is connected in parallel to each of a plurality of battery cells constituting a battery, a voltage detection circuit that detects a voltage of each of the battery cells, and a control unit that controls each of the switching elements such that the voltage of each of the battery cells is uniform based on a voltage detection result of each of the battery cells obtained from the voltage detection circuit, in which each of the switching elements of the discharge circuit connected to the adjacent battery cells is controlled at different duty ratios, and a disconnection of a wiring drawn out from both ends of each of the battery cells is detected based on a potential difference between the adjacent battery cells.

In addition, the cell balance control device balances (equalizes) the charging amount of the plurality of battery cells by forcibly discharging the battery cells by using the discharge circuit, in addition to the disconnection detection of the wiring. That is, when the cell voltage of the adjacent battery cell is higher than the cell voltage of a certain battery cell, the cell balance control device performs forced discharge (equalization discharge) by using the discharge circuit connected to the adjacent battery cell to equalize the charging amount of each of the battery cells.

### CITATION LIST

### Patent Document

Patent Document 1: Japanese Unexamined Patent Application, First Publication No. 2013-085354

### SUMMARY OF INVENTION

### Technical Problem

However, although not described in Patent Document 1, in the cell balance control device, a CR low-pass filter is included for each wiring. The CR low-pass filter is an additional circuit to remove noise or the like that arrives at the wiring and to more accurately detect the cell voltage and is provided in a portion of each wiring closer to the voltage detection circuit than to the discharge circuit.

In addition, some cell balance control devices are provided with a protection function for preventing overcurrent from flowing through the switching element (electronic switch) of the discharge circuit. When such a protection function is provided, in a case where a disconnection of the wiring occurs, a voltage that is twice a voltage normally applied can be applied to the electronic switch.

When each of such wirings is provided with the CR low-pass filter and the protection function is provided in the electronic switch of the discharge circuit, in a case where a disconnection occurs in a wiring on a low potential side connected to a certain battery cell during equalization discharge of the certain battery cell, the capacitor of the CR low-pass filter provided in the wiring on the low potential side is charged by a voltage that is twice a voltage normally applied.

However, since the protection function is operated by the doubled voltage, the electronic switch of the discharge circuit connected to the capacitor cannot be switched to an ON state, and electric charges of the capacitor cannot be discharged. When the capacitor is held in a charged state, a situation occurs in which a disconnection cannot be normally detected based on the cell voltage.

The present invention has been made in view of the above-described circumstances, and an object of the present invention is to provide a disconnection detection device and a battery monitoring device capable of normally detecting a disconnection of a wiring based on a cell voltage although each wiring includes a CR low-pass filter, and an electronic switch of a discharge circuit includes a protection function.

### Solution to Problem

A disconnection detection device according to a first aspect of the present disclosure includes, with respect to a battery including a plurality of battery cells that are connected in series to each other, each of which is connected in parallel to a discharge circuit that includes an electronic switch, a voltage detection circuit configured to detect a cell voltage of the battery cell, a CR low-pass filter provided in each of a plurality of wirings connecting the battery cell to the voltage detection circuit, and a control unit configured to perform equalization discharge of the discharge circuit and detect a disconnection of the wiring based on the cell voltage, in which the electronic switch has a protection function for prohibiting transition to an ON state, and the control unit performs electricity removal of electric charges accumulated in the CR low-pass filter by operating any one of a pair of the electronic switches related to a pair of the battery cells adjacent to each other and detects the disconnection of the wiring based on the cell voltage after the electricity removal.

In the disconnection detection device of a second aspect of the present disclosure, when a determination is made that the protection function of the electronic switch preset as an electricity removal switch of the CR low-pass filter is operated, the control unit performs the electricity removal for the CR low-pass filter by setting the electronic switch paired with the electronic switch, in which the protection function is operated, to the ON state.

In the disconnection detection device of a third aspect of the present disclosure, the control unit identifies the disconnection of the wiring and abnormality of the battery cell based on a differential voltage and a sum voltage of cell voltages of the pair of battery cells when at least one of the discharge circuits is discharged.

In the disconnection detection device of a fourth aspect of the present disclosure, the discharge circuit is a series circuit of the electronic switch and a resistor.

A battery monitoring device according to a first aspect of the present disclosure includes the disconnection detection device according to any one of the first to fourth aspects, and controls connection to a load of a battery based on a disconnection detection result of the disconnection detection device.

### Advantageous Effects of Invention

According to the present disclosure, it is possible to provide a disconnection detection device and a battery monitoring device capable of normally detecting a disconnection of a wiring based on a cell voltage although each wiring includes a CR low-pass filter, and an electronic switch of a discharge circuit includes a protection function.

### BRIEF DESCRIPTION OF DRAWINGS

FIG. 1 A block diagram showing a configuration of a battery monitoring device A according to an embodiment of the present disclosure.

FIG. 2 A flowchart showing an operation of the battery monitoring device A according to the embodiment of the present disclosure.

FIG. 3 A timing chart showing the operation of the battery monitoring device A according to the embodiment of the present disclosure.

FIG. 4 A first circuit diagram showing the operation of the battery monitoring device A according to the embodiment of the present disclosure.

FIG. 5A A first characteristic diagram showing the operation of the battery monitoring device A according to the embodiment of the present disclosure.

FIG. 5B A second characteristic diagram showing the operation of the battery monitoring device A according to the embodiment of the present disclosure.

### DESCRIPTION OF EMBODIMENTS

Hereinafter, an embodiment of the present invention will be described with reference to the drawings.

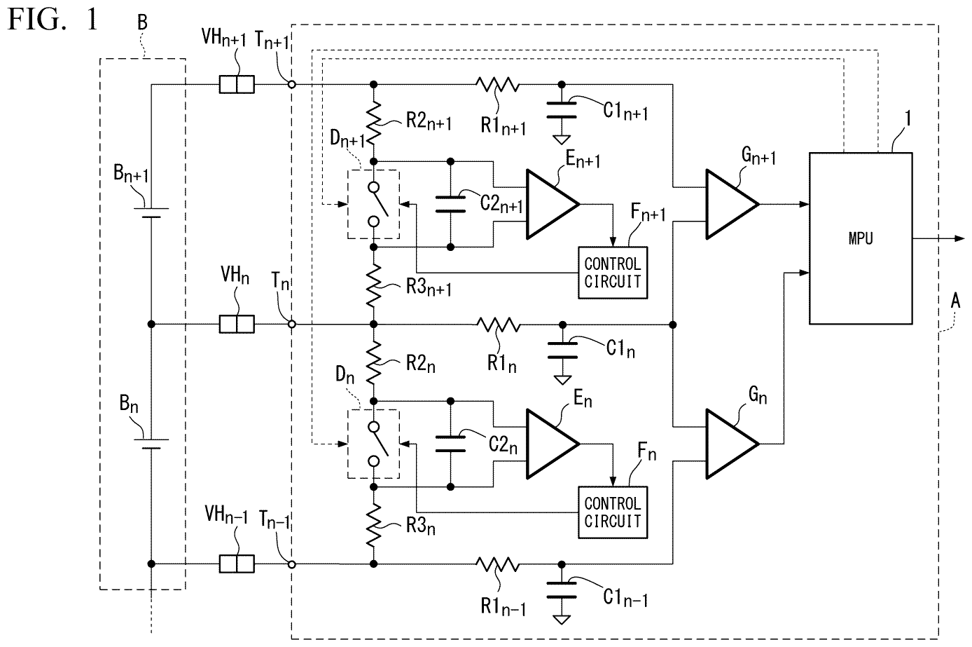

First, a functional configuration of a battery monitoring device A according to the present embodiment will be described with reference to FIG. 1.

The battery monitoring device A is mounted on an electrified vehicle such as an electric vehicle or a hybrid vehicle and monitors a battery B such as a lithium ion battery or a fuel cell as a target. The battery monitoring device A controls the connection of the battery B to a load based on the monitoring result (disconnection detection result) of the battery B.

In FIG. 1, a pair of battery cells Bₙ and Bₙ₊₁ adjacent to each other is shown for convenience, but the battery B is actually a plurality of (n+1) battery cells B₁, . . . , Bₙ, and Bₙ₊₁ connected in series. That is, the battery B has a voltage obtained by adding the output voltages of the first to (n+1)-th battery cells B₁ to Bₙ₊₁, that is, first to (n+1)-th cell voltages V₁ to Vₙ₊₁ as a battery voltage. It is noted that n is any natural number.

As shown in the drawing, each electrode of the first to (n+1)-th battery cells B₁ to Bₙ₊₁ is connected to each of input terminals T₁, . . . , Tₙ, and Tₙ₊₁ of the battery monitoring device A by a plurality of, that is, (n+1) wirings VH₁, . . . , VHₙ, and VHₙ₊₁. For example, the minus electrode of the n-th battery cell Bₙ is connected to the (n−1)-th input terminal Tₙ₋₁ of the battery monitoring device A by the first wiring VHₙ₋₁. That is, one end of the first wiring VHₙ₋₁ is connected to the minus electrode of the n-th battery cell Bₙ, and the other end is connected to the (n−1)-th input terminal Tₙ₋₁ of the battery monitoring device A.

The plus electrode of the n-th battery cell Bₙ and the minus electrode of the (n+1)-th battery cell Bₙ₊₁ are connected to the n-th input terminal Tₙ of the battery monitoring device A by the n-th wiring VHₙ. That is, one end of the n-th wiring VHₙ is connected to the plus electrode of the n-th battery cell Bₙ and the minus electrode of the (n+1)-th battery cell Bₙ₊₁, and the other end thereof is connected to the n-th input terminal Tₙ of the battery monitoring device A.

The plus electrode of the battery cell Bₙ₊₁ is connected to the (n+1)-th input terminal Tₙ₊₁ of the battery monitoring device A by the (n+1)-th wiring VHₙ₊₁. That is, one end of the (n+1)-th wiring VHₙ₊₁ is connected to the plus electrode of the (n+1)-th battery cell Bₙ₊₁, and the other end thereof is connected to the (n+1)-th input terminal Tₙ₊₁ of the battery monitoring device A.

That is, the battery monitoring device A according to the present embodiment is connected to the battery B by the (n+1) wirings VH₁, ..., VHₙ, and VHₙ₊₁. In the battery monitoring device A, when the disconnection occurs in any of the first to (n+1)-th wirings VH₁ to VHₙ₊₁, it is not possible to correctly detect the inter-electrode voltages, that is, the first to (n+1)-th cell voltages V₁ to Vₙ₊₁ of the first to (n+1)-th battery cells B₁ to Bₙ₊₁ in the battery B, and it is not possible to perform normal monitoring of the battery B.

Due to such circumstances, the battery monitoring device A is provided with a disconnection detection function for detecting disconnection of any one of the first to (n+1)-th wirings VH₁ to VHₙ₊₁. Although details will be described later, the battery monitoring device A according to the present embodiment is a disconnection detection device that detects disconnection in any of the first to (n+1)-th wirings VH₁ to VHₙ₊₁ based on the first to (n+1)-th cell voltages V₁ to Vₙ₊₁.

As shown in the drawing, the battery monitoring device A includes (n+1) first resistors R1₁ to R1ₙ₊₁, (n+1) second resistors R2₁ to R2ₙ₊₁, (n+1) third resistors R3₁ to R3ₙ₊₁, (n+1) first capacitors C1₁ to C1ₙ₊₁, (n+1) second capacitors C2₁ to C2ₙ₊₁, (n+1) electronic switches D₁ to Dₙ₊₁, (n+1) differential amplifiers E₁ to Eₙ₊₁, (n+1) control circuits F₁ to Fₙ₊₁, (n+1) voltage amplifiers G₁ to Gₙ₊₁, and an MPU 1, in addition to the first to (n+1)-th input terminals T₁ to Tₙ₊₁ described above.

Among the first to (n+1)-th input terminals T₁ to Tₙ₊₁, the (n−1)-th input terminal Tₙ₋₁ is connected to the other end of the (n−1)-th wiring VHₙ₋₁, one end of first resistor R1ₙ₋₁, and one end of the third resistor R3ₙ, as shown in the drawing. The n-th input terminal Tₙ is connected to each of the other end of the n-th wiring VHₙ, one end of the first resistor R1ₙ, one end of the second resistor R2ₙ, and one end of the third resistor R3ₙ₊₁. The (n+1)-th input terminal Tₙ₊₁ is connected to each of one end of the first resistor R1ₙ₊₁ and one end of the second resistor R2ₙ₊₁.

In the (n+1) first resistors R1₁ to R1ₙ₊₁, the (n+1) second resistors R2₁ to R2ₙ₊₁, and the (n+1) third resistors R3₁ to R3ₙ₊₁, one end of the first resistor R1ₙ₋₁ is connected to the (n−1)-th input terminal Tₙ₋₁ and one end of the third resistor R3ₙ, and the other end thereof is connected to one end of the first capacitor C1ₙ₋₁ and one input terminal in the n-th voltage amplifier Gₙ.

One end of the first resistor R1ₙ is connected to the n-th input terminal Tₙ, one end of_the second resistor R2ₙ, and one end of the third resistor R3ₙ₊₁, and the other end thereof is connected to one end of the first capacitor C1ₙ, the other input terminal in the n-th voltage amplifier Gₙ, and one input terminal in the (n+1)-th voltage amplifier Gₙ₊₁.

One end of the second resistor R2ₙ is connected to the n-th input terminal Tₙ, one end of the first resistor R1ₙ, and one end of the third resistor R3ₙ₊₁, and the other end thereof is connected to one end of the n-th electronic switch Dₙ, one end of the second capacitor C2ₙ, and one input terminal in the n-th differential amplifier Eₙ.

One end of the third resistor R3ₙ is connected to the (n−1)-th input terminal Tₙ₋₁ and one end of the first resistor R1ₙ₋₁, and the other end thereof is connected to the other end of the n-th electronic switch Dₙ, the other end of the second capacitor C2ₙ, and the other input terminal in the n-th differential amplifier Eₙ.

One end of the first resistor R1ₙ₊₁ is connected to one end of the (n+1)-th input terminal Tₙ₊₁ and the second resistor R2ₙ₊₁, and the other end thereof is connected to one end of the first capacitor C1ₙ₊₁ and the other input terminal in the (n+1)-th voltage amplifier Gₙ₊₁.

One end of the second resistor R2ₙ₊₁ is connected to the (n+1)-th input terminal Tₙ₊₁ and one end of the first resistor R1ₙ₊₁, and the other end thereof is connected to one end of the (n+1)-th electronic switch Dₙ₊₁, one end of the second capacitor C2ₙ₊₁, and one input terminal in the (n+1)-th differential amplifier Eₙ₊₁.

One end of the third resistor R3ₙ₊₁ is connected to the n-th input terminal Tₙ, one end of the first resistor R1ₙ, and one end of the second resistor R2ₙ, and the other end thereof is connected to the other end of the (n+1)-th electronic switch Dₙ₊₁, the other end of the second capacitor C2ₙ₊₁, and the other input terminal in the (n+1)-th differential amplifier Eₙ₊₁.

In the (n+1) first capacitors C1₁ to C1ₙ₊₁ and the (n+1) second capacitors C2₁ to C2ₙ₊₁, one end of the first capacitor C1ₙ₋₁ is connected to the other end of the first resistor R1ₙ₋₁ and one input terminal in the n-th voltage amplifier Gₙ, and the other end thereof is grounded. The first capacitor C1ₙ₋₁ and the first resistor R1ₙ₋₁ constitute an (n-1)-th CR low-pass filter.

One end of the first capacitor C1ₙ is connected to the other end of the first resistor R1ₙ, one input terminal of the n-th voltage amplifier Gₙ, and one input terminal in the (n+1)-th voltage amplifier Gₙ₊₁, and the other end thereof is grounded. The first capacitor C1ₙ and the first resistor R1ₙ constitute an n-th CR low-pass filter.

One end of the second capacitor C2ₙ is connected to the other end of the second resistor R2ₙ, one end of the n-th electronic switch Dₙ, and one input terminal in the n-th differential amplifier Eₙ, and the other end thereof is connected to the other end of the third resistor R3ₙ, the other end of the n-th electronic switch Dₙ, and the other input terminal in the n-th differential amplifier Eₙ.

One end of the first capacitor C1ₙ₊₁ is connected to the other end of the first resistor R1ₙ₊₁ and the other input terminal in the (n+1)-th voltage amplifier Gₙ₊₁, and the other end thereof is grounded. The first capacitor C1ₙ₊₁ and the first resistor R1ₙ₊₁ constitute an (n+1)-th CR low-pass filter.

One end of the second capacitor C2ₙ₊₁ is connected to the other end of the second resistor R2ₙ₊₁, one end of the (n+1)-th electronic switch Dₙ₊₁, and one input terminal in the (n+1)-th differential amplifier Eₙ₊₁, and the other end thereof is connected to the other end of the third resistor R3ₙ₊₁, the other end of the (n+1)-th electronic switch Dₙ₊₁, and the other input terminal in the (n+1)-th differential amplifier Eₙ₊₁.

In the (n+1) electronic switches D₁ to Dₙ₊₁, one end of the n-th electronic switch Dₙ is connected to the other end of the second resistor R2ₙ, one end of the second capacitor C2ₙ, and one input terminal in the n-th differential amplifier En, and the other end thereof is connected to the other end of the third resistor R3ₙ, the other end of the second capacitor C2ₙ, and the other input terminal in the n-th differential amplifier Eₙ.

A pair of input terminals are provided in the n-th electronic switch Dₙ. In the pair of input terminals in the n-th electronic switch Dₙ, one input terminal thereof is connected to the output terminal in the n-th control circuit Fₙ, and the other input terminal thereof is connected to one of a pair of output terminals in the MPU 1.

One end of the (n+1)-th electronic switch Dₙ₊₁ is connected to the other end of the second resistor R2ₙ₊₁, one end of the second capacitor C2ₙ₊₁, and one input terminal in the (n+1)-th differential amplifier Eₙ₊₁, and the other end thereof is connected to the other end of the third resistor R3ₙ₊₁, the other end of the second capacitor C2ₙ₊₁, and the other input terminal in the (n+1)-th differential amplifier Eₙ₊₁.

The (n+1)-th electronic switch Dₙ₊₁ is provided with a pair of input terminals. In a pair of input terminals in the (n+1)-th electronic switch Dₙ₊₁, one input terminal thereof is connected to the output terminal in the (n+1)-th control circuit Fₙ₊₁, and the other input terminal thereof is connected to the other one of the pair of output terminals in the MPU 1. The n-th electronic switch Dₙ and the (n+1)-th electronic switch Dₙ₊₁ are adjacent to each other and are electronic switches forming a pair.

Here, the second resistor R2ₙ, the third resistor R3ₙ, and the n-th electronic switch Dₙdescribed above constitute an n-th series circuit. The n-th series circuit is an n-th discharge circuit that is connected in parallel to the n-th battery cell Bₙ. That is, when the n-th electronic switch Dₙ is set to an ON state, the n-th discharge circuit forcibly discharges the electric charges charged in the n-th battery cell Bₙ to the second resistor R2ₙ and the third resistor R3ₙ as discharge resistors.

In addition, the second resistor R2ₙ₊₁, the third resistor R3ₙ₊₁, and the (n+1)-th electronic switch Dₙ₊₁ constitute a (n+1)-th series circuit. The (n+1)-th series circuit is an (n+1)-th discharge circuit that is connected in parallel to the (n+1)-th battery cell Bₙ₊₁. That is, when the (n+1)-th electronic switch Dₙ₊₁ is set to the ON state, the (n+1)-th discharge circuit forcibly discharges the electric charges charged in the (n+1)-th battery cell Bₙ₊₁ to the second resistor R2ₙ₊₁ and the third resistor R3ₙ₊₁ as discharge resistors.

In the (n+1) differential amplifiers E₁ to Eₙ₊₁, one input terminal of the n-th differential amplifier Eₙ is connected to the other end of the second resistor R2ₙ, one end of the n-th electronic switch Dₙ, and one end of the second capacitor C2ₙ, the other input terminal thereof is connected to the other end of the third resistor R3ₙ, the other end of the n-th electronic switch Dₙ, and the other end of the second capacitor C2ₙ, and the output terminal thereof is connected to the input terminal of the n-th differential amplifier Eₙ.

That is, the n-th differential amplifier Eₙ amplifies an inter-terminal voltage in the n-th electronic switch Dₙ. The n-th differential amplifier En outputs the inter-terminal voltage as an n-th detection voltage to the n-th control circuit Fₙ.

One input terminal of the (n+1)-th differential amplifier Eₙ₊₁ is connected to the other end of the second resistor R2ₙ₊₁, one end of the (n+1)-th electronic switch Dₙ₊₁, and one end of the second capacitor C2ₙ₊₁, the other input terminal thereof is connected to the other end of the third resistor R3ₙ₊₁, the other end of the (n+1)-th electronic switch Dₙ₊₁, and the other end of the second capacitor C2ₙ₊₁, and the output terminal thereof is connected to the input terminal of the (n+1)-th differential amplifier Eₙ₊₁.

The (n+1)-th differential amplifier Eₙ₊₁ amplifies an inter-terminal voltage in the (n+1)-th electronic switch Dₙ₊₁. The (n+1)-th differential amplifier Eₙ₊₁ outputs the inter-terminal voltage as an (n+1)-th detection voltage to the (n+1)-th control circuit Fₙ₊₁.

In the (n+1) control circuits F₁ to Fₙ₊₁, the input terminal of the n-th control circuit Fₙ is connected to the output terminal of the n-th differential amplifier Eₙ, and the output terminal thereof is connected to one input terminal in the n-th electronic switch Dn. The n-th control circuit Fn controls an open state/closed state of the n-th electronic switch Dₙ based on the n-th detection voltage inputted from the n-th differential amplifier Eₙ.

The input terminal of the (n+1)-th control circuit Fₙ₊₁ is connected to the output terminal of the (n+1)-th differential amplifier Eₙ₊₁, and the output terminal thereof is connected to one input terminal of the (n+1)-th electronic switch Dₙ₊₁. The (n+1)-th control circuit Fₙ₊₁ controls an open state/closed state of the (n+1)-th electronic switch Dₙ₊₁ based on the (n+1)-th detection voltage inputted from the (n+1)-th differential amplifier Eₙ₊₁.

Here, the (n+1) differential amplifiers E₁ to Eₙ₊₁ and the (n+1) control circuits F₁ to Fₙ₊₁ are components attached to each of the first to (n+1)-th electronic switches D₁ to Dₙ₊₁. The n-th differential amplifier Eₙ and the n-th control circuit Fₙ are provided to be attached to the n-th electronic switch Dₙ, and the (n+1)-th differential amplifier Eₙ₊₁ and the (n+1)-th control circuit Fₙ₊₁ are provided to be attached to the (n+1)-th electronic switch Dₙ₊₁.

That is, the n-th electronic switch Dₙ is provided with an n-th overcurrent protection function based on the n-th differential amplifier Eₙ and the n-th control circuit _{Fn}, and the (n+1)-th electronic switch Dₙ₊₁ is provided with an (n+1)-th overcurrent protection function based on the (n+1)-th differential amplifier Eₙ₊₁ and the (n+1)-th control circuit Fₙ₊₁.

When an overvoltage is applied between one end and the other end, that is, between the terminals of the n-th electronic switch Dₙ, the n-th overcurrent protection function prohibits the n-th electronic switch Dₙ from transitioning to the ON state such that an overcurrent does not flow to the n-th electronic switch Dₙ. When an overvoltage is applied between one end and the other end, that is, between the terminals of the (n+1)-th electronic switch Dₙ₊₁, the (n+1)-th overcurrent protection function prohibits the (n+1)-th electronic switch Dₙ₊₁ from transitioning to the ON state such that an overcurrent does not flow to the (n+1)-th electronic switch Dₙ₊₁.

The (n+1) voltage amplifiers G₁ to Gₙ₊₁ are voltage detection circuits that detect (calculate) the first to (n+1)-th cell voltages V₁ to Vₙ₊₁ (inter-electrode voltages) of the first to (n+1)-th battery cells B₁ to Bₙ₊₁. In the voltage amplifiers G₁ to Gₙ₊₁, the one input terminal of the n-th voltage amplifier Gₙ is connected to the other end of the first resistor R1ₙ₋₁ and one end of the first capacitor C1ₙ₋₁, the other input terminal thereof is connected to the other end of the first resistor R1ₙ, one end of the first capacitor C1ₙ, and one input terminal of the (n+1)-th voltage amplifier Gₙ₊₁, and the output terminal thereof is connected to the n-th input terminal of the MPU 1.

The n-th voltage amplifier Gₙ amplifies a difference between an (n−1)-th battery potential applied from the minus electrode of the n-th battery cell Bₙ through the (n−1)-th wiring VHₙ₋₁ and the (n−1)-th CR low-pass filter and an n-th battery potential applied from the plus electrode of the n-th battery cell Bₙ through the n-th wiring VHₙ and the n-th CR low-pass filter. That is, the n-th voltage amplifier Gₙ outputs an inter-electrode voltage related to the n-th battery cell Bₙ as the n-th cell voltage Vₙ to the n-th input terminal of the MPU 1.

One input terminal of the (n+1)-th voltage amplifier Gₙ₊₁ is connected to the other end of the first resistor R1ₙ, one end of the first capacitor C1ₙ, and the other input terminal in the n-th voltage amplifier Gₙ, the other input terminal thereof is connected to the other end of the first resistor R1ₙ₊₁ and one end of the first capacitor C1ₙ₊₁, and the output terminal thereof is connected to an (n+1)-th input terminal in the MPU 1.

The (n+1)-th voltage amplifier Gₙ₊₁ amplifies a difference between the n-th battery potential applied from the plus electrode of the n-th battery cell Bₙ and the minus electrode of the (n+1)-th battery cell Bₙ₊₁ through the n-th wiring VHₙ and the n-th CR low-pass filter, and an (n+1)-th battery potential applied from the plus electrode of the (n+1)-th battery cell Bₙ₊₁ through the (n+1)-th wiring VHₙ₊₁ and the (n+1)-th CR low-pass filter. That is, the (n+1)-th voltage amplifier Gₙ₊₁ outputs the inter-electrode voltage related to the (n+1)-th battery cell Bₙ₊₁ as the (n+1)-th cell voltage Vₙ₊₁ to the (n+1)-th input terminal of the MPU 1.

The MPU 1 includes at least (n+1) input terminals and (n+1) output terminals. Among the (n+1) input terminals, the n-th input terminal is connected to the output terminal of the n-th voltage amplifier Gₙ, and the (n+1)-th input terminal is connected to the output terminal of the (n+1)-th voltage amplifier Gₙ₊₁. In addition, the n-th output terminal is connected to the other input terminal in the n-th electronic switch Dₙ, and the (n+1)-th output terminal is connected to the other input terminal in the (n+1)-th electronic switch Dₙ₊₁.

Such MPU 1 includes a storage circuit that stores at least a predetermined monitoring program, an arithmetic circuit that executes the monitoring program, and an input/output circuit that performs input and output of signals with the (n+1) electronic switches D₁ to Dₙ₊₁, the (n+1) voltage amplifiers G₁ to Gₙ₊₁, or the like. The MPU 1 is a control unit that controls opening and closing of the first to (n+1)-th electronic switches D₁ to Dₙ₊₁, that is, the operation of the first to (n+1)-th discharge circuits by executing a monitoring program of the storage circuit in the arithmetic circuit.

That is, the MPU 1 generates first to (n+1)-th switching signals based on the first to (n+1)-th cell voltages V₁ to Vₙ₊₁ inputted from the first to (n+1)-th voltage amplifiers G₁ to Gₙ₊₁. The MPU 1 controls the opening and closing of the first to (n+1)-th electronic switches D₁ to Dₙ₊₁, that is, the operation of the first to (n+1)-th discharge circuits by outputting the first to (n+1)-th switching signals to the other input terminal each of the corresponding first to (n+1)-th electronic switches D₁ to Dₙ₊₁.

The battery monitoring device A (disconnection detection device) includes each of the first to (n+1)-th CR low-pass filters in each of the first to (n+1)-th wirings VH₁ to VHₙ₊₁, and each of the first to (n+1)-th electronic switches D₁ to Dₙ₊₁ in the first to (n+1)-th discharge circuits is provided with each of the first to (n+1)-th overcurrent protection functions.

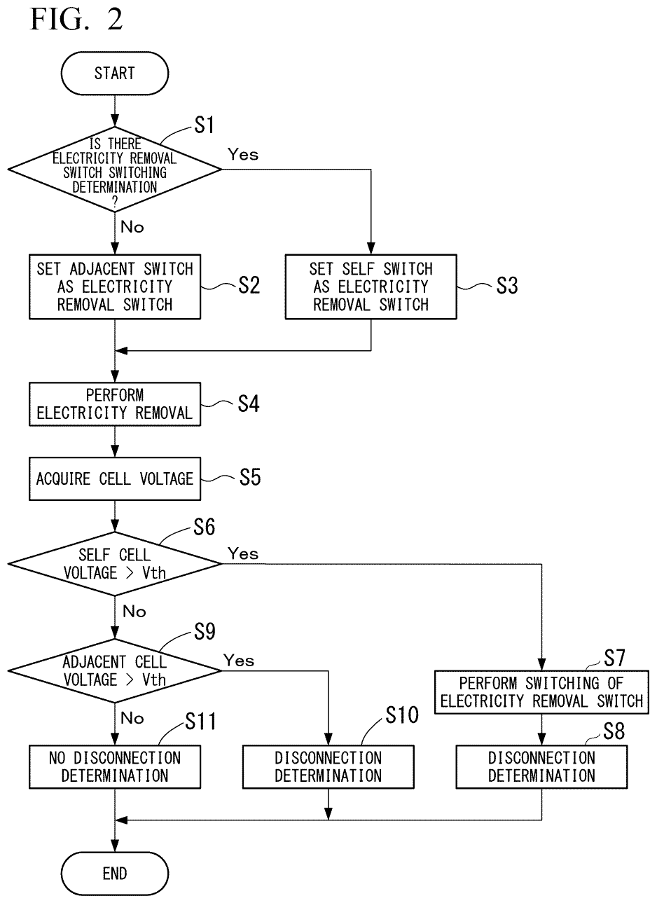

Next, the operation of the battery monitoring device A according to the present embodiment will be described with reference to the flowchart shown in FIG. 2.

In the following, the disconnection detection for the battery cells Bₙ and Bₙ₊₁ adjacent to each other will be described. In the operation description, the (n+1)-th battery cell Bₙ₊₁ is referred to as a self cell, the (n+1)-th electronic switch Dₙ₊₁ is referred to as a self switch, the n-th battery cell Bₙ is referred to as an adjacent cell, and the n-th electronic switch Dₙ is referred to as an adjacent switch.

First, in order to equalize the charged states of the (n+1) battery cells B₁, . . . , Bₙ, and Bₙ₊₁, the battery monitoring device A (disconnection detection device) according to the present embodiment includes a circuit configuration in which, when disconnection occurs in a wiring on a low potential side connected to a certain battery cell during the equalization discharge of the certain battery cell, a capacitor of a CR low-pass filter provided in the wiring on the low potential side is charged by a voltage that is about twice a voltage normally applied.

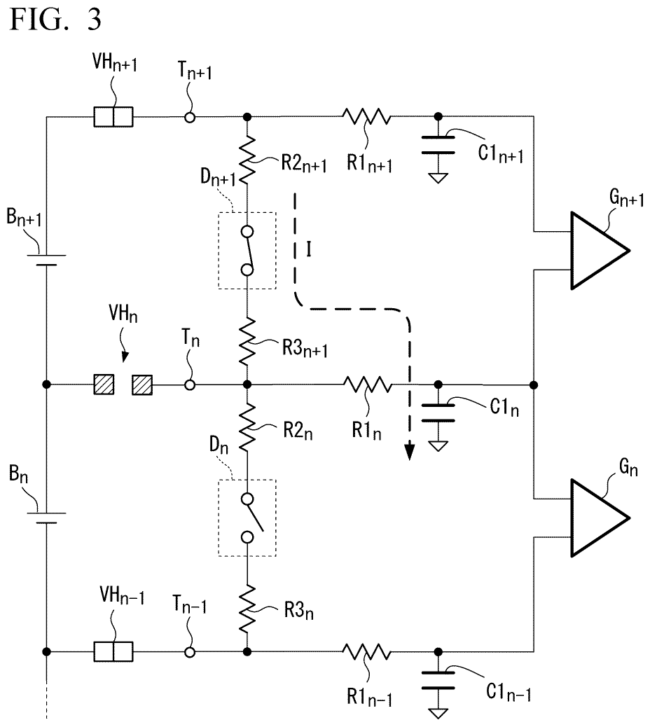

For example, as shown in FIG. 3, in a state where the (n+1)-th electronic switch Dₙ₊₁ (self switch) is set to the ON state and the (n+1)-th battery cell Bₙ₊₁ (self cell) is equally discharged, when the n-th wiring VHₙ is disconnected, a current I shown by a broken line flows, and a voltage of the plus terminal of the (n+1)-th battery cell Bₙ₊₁ (self cell) is applied to the first capacitor C1ₙ instead of a voltage of the plus terminal of the n-th battery cell Bₙ (adjacent cell).

Since the n-th battery cell Bₙ (adjacent cell) and the (n+1)-th battery cell Bₙ₊₁ (self cell) are connected in series, and the n-th cell voltage Vₙ of the n-th battery cell Bₙ (adjacent cell) and the (n+1)-th cell voltage Vₙ₊₁ of the (n+1)-th battery cell Bₙ₊₁ (self cell) are substantially the same, the voltage of the plus terminal of the (n+1)-th battery cell Bₙ₊₁ (self cell) corresponds to about twice the voltage of the plus terminal of the n-th battery cell Bₙ (adjacent cell). The first capacitor C1ₙ is charged by about the doubled voltage, and the potential of one end thereof is held at about the doubled voltage.

Although details will be described later, the MPU 1 of the battery monitoring device A detects the first to (n+1)-th cell voltages V₁ to Vₙ₊₁ based on the first to (n+1)-th difference voltages inputted from the first to (n+1)-th voltage amplifiers G₁ to Gₙ₊₁, and detects the disconnection of the first to (n+1)-th wirings VH₁ to VHₙ₊₁ by using the first to (n+1)-th cell voltages V₁ to Vₙ₊₁.

However, when the potential of one end of the first capacitor C1ₙ is held at about the doubled voltage, that is, when the n-th wiring VHₙ is disconnected, the n-th and (n+1)-th cell voltages Vₙ and Vₙ₊₁ are abnormal voltage values. That is, the n-th cell voltage Vₙ is a voltage value that is about twice the normal cell voltage. On the other hand, the (n+1)-th cell voltage Vₙ₊₁ is a voltage value of substantially zero.

When the n-th wiring VHₙ is disconnected in this manner, the n-th and (n+1)-th cell voltages Vₙ and Vₙ₊₁ are abnormal voltage values, but the abnormal voltage values in the n-th and (n+1)-th cell voltages Vₙ and Vₙ₊₁ occur not only when the n-th wiring VHₙ is disconnected but also when the n-th battery cell Bₙ (adjacent cell) or the (n+1)-th battery cell Bₙ₊₁ (self cell) is abnormal. In order to distinguish and detect the disconnection of the n-th wiring VHₙ from the abnormality of the n-th battery cell Bₙ (adjacent cell) or the (n+1)-th battery cell Bₙ₊₁ (self cell), it is necessary to evaluate the change tendency of a differential voltage Vdiff and a sum voltage Vsum of the n-th and (n+1)-th cell voltages Vₙ and Vₙ₊₁ of the n-th battery cell Bₙ (adjacent cell) and the (n+1)-th battery cell Bₙ₊₁ (self cell) adjacent to each other.

When the MPU 1 detects an abnormality in the n-th and (n+1)-th cell voltages Vₙ and Vₙ₊₁, the first capacitor C1ₙ is discharged by setting the n-th electronic switch Dₙ (adjacent switch) designated in advance to the ON state. That is, since the n-th and (n+1)-th cell voltages Vₙ and Vₙ₊₁ are abnormal during the equalization discharge of the (n+1)-th battery cell Bₙ₊₁ (self cell), the first capacitor C1ₙ is once discharged (electricity-removed), and then the n-th and (n+1)-th cell voltages Vₙ and Vₙ₊₁ are detected again.

When the first capacitor C1ₙ is electricity-removed, the MPU 1 determines whether or not there is an electricity removal switch switching determination (step S1). Here, the MPU 1 determines that “there is an electricity removal switch switching determination” when the n-th cell voltage Vₙ exceeds a predetermined threshold value and determines that “there is no electricity removal switch switching determination” when the n-th cell voltage Vₙ is equal to or less than the predetermined threshold value.

That is, the MPU 1 determines that the n-th overcurrent protection function of the n-th electronic switch Dₙ (adjacent switch) is operated when the n-th cell voltage Vₙ exceeds the predetermined threshold value, and determines that the n-th overcurrent protection function of the n-th electronic switch Dₙ (adjacent switch) is not operated when the n-th cell voltage Vₙ is equal to or less than the predetermined threshold value. Then, when the determination in the step S1 is “No”, that is, when a determination is made that the n-th overcurrent protection function of the n-th electronic switch Dₙ (adjacent switch) is not operated, the MPU 1 sets the n-th electronic switch Dₙ (adjacent switch) as an electricity removal switch (step S2).

On the other hand, when the determination in the step S1 is “Yes”, that is, when it is determined that the overcurrent protection function of the n-th electronic switch Dₙ (adjacent switch) is operated, the MPU 1 sets the (n+1)-th electronic switch Dₙ₊₁ (self switch) as the electricity removal switch (step S3). Then, the MPU 1 performs electricity removal from the first capacitor C1ₙ by operating the electricity removal switch (sets the electricity removal switch to the ON state) (step S4).

When the n-th electronic switch Dₙ (adjacent switch) is set as the electricity removal switch, the electric charges accumulated in the first capacitor C1ₙ are electricity-removed through the first resistor R1ₙ→the second resistor R2ₙ→the n-th electronic switch Dₙ (adjacent switch)→the third resistor R3ₙ→the first resistor R1ₙ₋₁→the first capacitor C1ₙ₋₁.

When the (n+1)-th electronic switch Dₙ₊₁ (self switch) is set as the electricity removal switch, the electric charges accumulated in the first capacitor C1ₙ is electricity-removed through the first resistor R1ₙ→the third resistor R3ₙ₊₁→the (n+1)-th electronic switch Dₙ₊₁ (self switch) second resistor R2ₙ₊₁→the first resistor R1ₙ₊₁→the first capacitor C1ₙ₊₁.

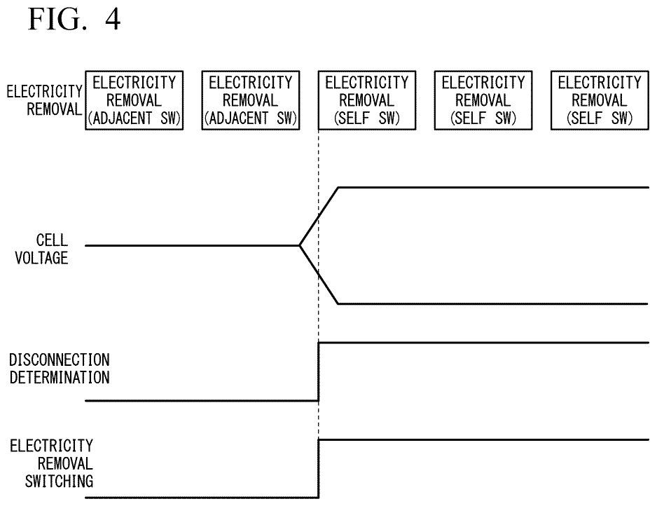

That is, as shown in FIG. 4, the electricity removal switch is switched in time series according to the operating state of the n-th overcurrent protection function. Therefore, a situation in which the electric charges accumulated in the first capacitor C1ₙ cannot be electricity-removed due to the fixation of the electricity removal switch does not occur.

When the electricity-removed of the first capacitor C1ₙ is completed in this manner, the MPU 1 acquires the n-th and (n+1)-th cell voltages Vₙ and Vₙ₊₁ of the n-th battery cell Bₙ (adjacent cell) and the (n+1)-th battery cell Bₙ₊₁ (self cell) (step S5). Then, the MPU 1 determines whether or not the (n+1)-th cell voltage Vₙ₊₁ of the (n+1)-th battery cell Bₙ₊₁ (self cell) exceeds a voltage threshold value Vth (step S6).

When the determination in the step S6 is “Yes”, the MPU 1 switches the electricity removal switch (step S7). That is, when the n-th electronic switch Dₙ adjacent switch) is set as the electricity removal switch in the step S2, the MPU 1 changes the electricity removal switch to the (n+1)-th electronic switch Dₙ₊₁ (self switch).

On the other hand, when the (n+1)-th electronic switch Dₙ₊₁ (self switch) is set as the electricity removal switch in the step S3, the MPU 1 changes the electricity removal switch to the n-th electronic switch Dₙ (adjacent switch). Then, the MPU 1 performs the disconnection determination after performing switching of the electricity removal switch (step S8) and ends the disconnection evaluation processing.

As described above, the disconnection determination is performed by using the change tendency of the n-th and (n+1)-th cell voltages Vₙ and Vₙ₊₁, the differential voltage Vdiff between the n-th cell voltage Vₙ and the (n+1)-th cell voltage Vₙ₊₁, and the sum voltage Vsum between the n-th cell voltage Vₙ and the (n+1)-th cell voltage Vₙ₊₁ of the n-th battery cell Bₙ (adjacent cell) and the (n+1)-th battery cell Bₙ₊₁ (self cell) adjacent to each other.

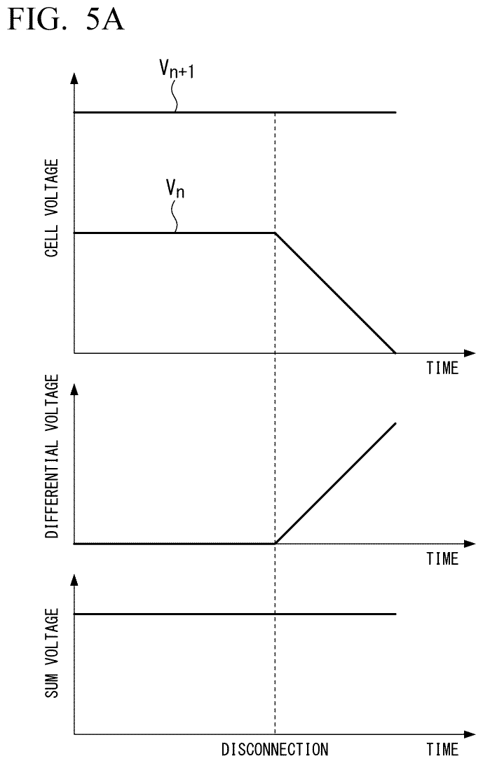

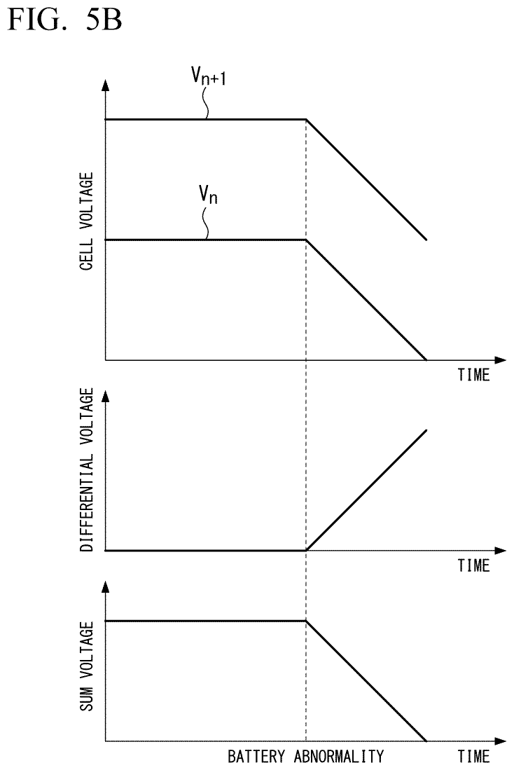

When the n-th battery cell Bₙ (adjacent cell) is gradually discharged by turning any one of the n-th discharge circuit and the (n+1)-th discharge circuit, for example, the n-th discharge circuit ON/OFF at a predetermined duty ratio, the (n+1)-th cell voltage Vₙ₊₁ does not change although the disconnection of the n-th wiring VHn occurs, as shown in FIG. 5A, but the n-th cell voltage Vₙ gradually decreases due to the disconnection of the n-th wiring VHₙ.

In addition, the differential voltage Vdiff in this case gradually increases due to the disconnection of the n-th wiring VHₙ. On the other hand, the sum voltage Vsum does not change although the n-th wiring VHₙ is disconnected. That is, when the n-th wiring VHₙ is disconnected, the change tendency (slope) of the differential voltage Vdiff and the sum voltage Vsum is completely different.

On the other hand, in a case where the n-th battery cell Bₙ (adjacent cell) is gradually discharged by turning the n-th discharge circuit ON/OFF at a predetermined duty ratio, when a voltage abnormality (battery abnormality) occurs in the n-th battery cell Bₙ (adjacent cell), both the n-th cell voltage Vₙ and the (n+1)-th cell voltage Vₙ₊₁ gradually decrease as shown in FIG. 5B.

In addition, the differential voltage Vdiff gradually increases when a voltage abnormality (battery abnormality) occurs in the n-th battery cell Bₙ (adjacent cell). On the other hand, the sum voltage Vsum gradually decreases when a voltage abnormality (battery abnormality) occurs in the n-th battery cell Bₙ (adjacent cell). That is, when a voltage abnormality (battery abnormality) occurs in the n-th battery cell Bₙ (adjacent cell), the absolute values of the differential voltage Vdiff and the sum voltage Vsum are the same although the directions of the change tendency (slope) thereof are different.

The MPU 1 detects the disconnection of the n-th wiring VHₙ by distinguishing the disconnection from the voltage abnormality (battery abnormality) of the n-th battery cell Bₙ (adjacent cell) by using the properties of the n-th, (n+1)-th cell voltages Vₙ and Vₙ₊₁, the differential voltage Vdiff between the n-th cell voltage Vₙ and the (n+1)-th cell voltage Vₙ₊₁, and the sum voltage Vsum between the n-th cell voltage Vₙ and the (n+1)-th cell voltage Vₙ₊₁.

When the determination in the step S6 is “No”, the MPU 1 determines whether or not the n-th cell voltage Vₙ of the n-th battery cell Bₙ (adjacent cell) exceeds the voltage threshold value Vth (step S9). Then, when the determination in the step S9 is “Yes”, the MPU 1 performs the disconnection determination (step S10), and, in a case where the determination in the step S9 is “No”, ends the disconnection evaluation processing with a determination that there is no disconnection (step S11).

According to the present embodiment, since the discharge switch (electronic switch) for discharging the capacitor of the CR low-pass filter charged with a doubled voltage can be changed without being fixed, it is possible to normally detect the disconnection of the wiring based on the cell voltage although each of the wirings includes the CR low-pass filter and the electronic switch of the discharge circuit has the overcurrent protection function.

That is, according to the present embodiment, the overcurrent protection function is operated due to the doubled voltage applied to the capacitor of the CR low-pass filter, the discharge switch (electronic switch) of the discharge circuit connected to the capacitor cannot be switched to the ON state, and the electric charges of the capacitor cannot be discharged. As a result, according to the present embodiment, it is possible to provide the battery monitoring device A (disconnection detection device) capable of avoiding a disconnection detection failure situation caused by a capacitor being held in a charged state.

Furthermore, the present invention is not limited to the above-described embodiments, and for example, the following modification examples are considered.

(1) In the above-described embodiment, the disconnection of the n-th wiring VHₙ is detected by using the properties of the n-th, (n+1)-th cell voltages Vₙ and Vₙ₊₁ that are adjacent to each other, the differential voltage Vdiff between the n-th cell voltage Vn and the (n+1)-th cell voltage Vₙ₊₁, and the sum voltage Vsum between the n-th cell voltage Vₙ and the (n+1)-th cell voltage Vₙ₊₁, but the present invention is not limited thereto.

For example, as described in Japanese Unexamined Patent Application, First Publication, No. 2017-158269, the disconnection of a transmission line and the voltage abnormality (battery abnormality) of a battery cell may be identified by using the differential voltage Vdiff and the sum voltage Vsum in a case where a pair of battery cells adjacent to each other is set in a discharged state with different duty ratios.

(2) In the above-described embodiment, the disconnection detection in the battery B (combined battery) mounted on the electrified vehicle has been described, but the present invention is not limited to this. The present invention can also be applied to a battery other than the in-vehicle battery B (combined battery).

### INDUSTRIAL APPLICABILITY

The present disclosure can be used for a disconnection detection device and a battery monitoring device.

1. A disconnection detection device comprising:
with respect to a battery including a plurality of battery cells that are connected in series to each other, each of which is connected in parallel to a discharge circuit that includes an electronic switch,
a voltage detection circuit configured to detect a cell voltage of the battery cell;
a CR low-pass filter provided in each of a plurality of wirings connecting the battery cell to the voltage detection circuit; and
a control unit configured to perform equalization discharge of the discharge circuit and detect a disconnection of the wiring based on the cell voltage, wherein
the electronic switch has a protection function for prohibiting transition to an ON state, and
the control unit performs electricity removal of electric charges accumulated in the CR low-pass filter by operating any one of a pair of the electronic switches related to a pair of the battery cells adjacent to each other and detects the disconnection of the wiring based on the cell voltage after the electricity removal.

2. The disconnection detection device according to claim 1, wherein
when a determination is made that the protection function of the electronic switch preset as an electricity removal switch of the CR low-pass filter is operated, the control unit performs the electricity removal for the CR low-pass filter by setting the electronic switch paired with the electronic switch, in which the protection function is operated, to the ON state.

3. The disconnection detection device according to claim 1, wherein
the control unit identifies the disconnection of the wiring and abnormality of the battery cell based on a differential voltage and a sum voltage of cell voltages of the pair of battery cells when at least one of the discharge circuits is discharged.

4. The disconnection detection device according to claim 1, wherein
the discharge circuit is a series circuit of the electronic switch and a resistor.

5. A battery monitoring device comprising:
the disconnection detection device according to claim 1, wherein
connection to a load of a battery is controlled based on a disconnection detection result of the disconnection detection device.

6. The disconnection detection device according to claim 2, wherein
the control unit identifies the disconnection of the wiring and abnormality of the battery cell based on a differential voltage and a sum voltage of cell voltages of the pair of battery cells when at least one of the discharge circuits is discharged.

7. The disconnection detection device according to claim 2, wherein the discharge circuit is a series circuit of the electronic switch and a resistor.

8. The disconnection detection device according to claim 3, wherein the discharge circuit is a series circuit of the electronic switch and a resistor.

9. The disconnection detection device according to claim 6, wherein the discharge circuit is a series circuit of the electronic switch and a resistor.

10. A battery monitoring device comprising:
the disconnection detection device according to claim 2, wherein connection to a load of a battery is controlled based on a disconnection detection result of the disconnection detection device.

11. A battery monitoring device comprising:
the disconnection detection device according to claim 3, wherein connection to a load of a battery is controlled based on a disconnection detection result of the disconnection detection device.

12. A battery monitoring device comprising:
the disconnection detection device according to claim 4, wherein connection to a load of a battery is controlled based on a disconnection detection result of the disconnection detection device.

13. A battery monitoring device comprising:
the disconnection detection device according to claim 6, wherein connection to a load of a battery is controlled based on a disconnection detection result of the disconnection detection device.

14. A battery monitoring device comprising:
the disconnection detection device according to claim 7, wherein connection to a load of a battery is controlled based on a disconnection detection result of the disconnection detection device.

15. A battery monitoring device comprising:
the disconnection detection device according to claim 8, wherein connection to a load of a battery is controlled based on a disconnection detection result of the disconnection detection device.

16. A battery monitoring device comprising:
the disconnection detection device according to claim 9, wherein connection to a load of a battery is controlled based on a disconnection detection result of the disconnection detection device.
